(19) United States
(12) Patent Application Publication
(10) Pub. No.: US 2025/0199044 A1
(43) Pub. Date: Jun. 19, 2025

(54) ELECTROMAGNETIC WAVE DETECTION DEVICE AND METHOD OF CONTROLLING SAME

(71) Applicants: Hyundai Motor Company, Seoul (KR); Kia Corporation, Seoul (KR); NCT SOLUTIONS, Seoul (KR)

(72) Inventors: Jun-Byung CHAE, Hwaseong-Si (KR); Yoon-Jong Huh, Seoul (KR); Ook Kim, Seoul (KR)

(73) Assignees: Hyundai Motor Company, Seoul (KR); Kia Corporation, Seoul (KR); NCT SOLUTIONS, Seoul (KR)

(21) Appl. No.: 18/955,803

(22) Filed: Nov. 21, 2024

(30) Foreign Application Priority Data
Dec. 14, 2023 (KR) 10-2023-0182317

(51) Int. Cl. G01R 29/08

(52) U.S. Cl. CPC G01R 29/0871; G01R 29/0814

(57) ABSTRACT

An electromagnetic wave detection device in which a frequency detector including a fast response rate and a function of classifying electromagnetic waves and generating a warning signal are embedded in a single chip device. The electromagnetic wave detection device includes a receiving end portion configured to receive at least one antenna signal from an antenna block and generate at least one conversion signal, a switch configured to perform switching to change a gain according to characteristics of the at least one antenna signal and generate the at least one conversion signal, a frequency power detector configured to generate frequency information and power information using the at least one conversion signal, and a symptom detector configured to classify an electromagnetic wave using the frequency information and the power information.

### CROSS-REFERENCE TO RELATED APPLICATION

The present application claims priority to Korean Patent Application No. 10-2023-0182317, filed on Dec. 14, 2023, the entire contents of which is incorporated herein for all purposes by this reference.

### BACKGROUND OF THE PRESENT DISCLOSURE

### Field of the Present Disclosure

The present disclosure relates to electromagnetic wave detection technology, and more particularly, to a device having embedded therein a function and software capable of analyzing frequency characteristics and/or time characteristics of electromagnetic waves.

### Description of Related Art

Electromagnetic interference (EMI) from electromagnetic waves affects the reliable operation of electronics. The impact of EMI on systems is increasing due to high data transfer rates and energy minimization for low power.

Intentional electromagnetic interference (IEMI) is not EMI caused by the components of the system, but high-energy EMI with a malicious intent.

As highly complex systems such as autonomous driving are used, new attempts to attack such systems are emerging. Attempts to disable or misbehave systems such as vehicles, drones, and robots are expected to continue to evolve. As a result, it becomes increasingly important to detect such deliberate attacks at an early stage and to develop countermeasures accordingly.

However, a system for detecting such electromagnetic waves includes a relatively large volume and is controlled by a separate computer or the like. Accordingly, the problem is that it is difficult to implement the system as a small, lightweight, low-power, and low-cost system, and it is impossible to embed and use a plurality of detection systems in the system.

Furthermore, with the increase in more advanced intrusion and/or disturbance methods using EMI, there is an increasing need to analyze frequencies and patterns of EMI at a faster rate.

On the other hand, to construct a detection system to identify the aspect of such signals with ns-level precision, high-speed output signals are required, but miniaturization/lighting is difficult due to the large number of output signal lines and power consumption required therefor.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an electromagnetic wave detection device in which a frequency detector including a fast response rate and a function of classifying electromagnetic waves by analyzing the detection signal are embedded in a single chip device, and a method of controlling the same.

Furthermore, another objective of the present disclosure is to provide an electromagnetic wave detection device which may be implemented as a small, lightweight, low-power, and low-cost device and may be disposed in a plurality in a system for detecting electromagnetic waves and a method of controlling the same.

In an aspect, the present disclosure provides an electromagnetic wave detection device in which a frequency detector including a fast response rate and a function of classifying electromagnetic waves and generating a warning signal are embedded in a single chip device.

The electromagnetic wave detection device includes:
a receiving end portion configured to receive at least one antenna signal from an antenna block and generate at least one conversion signal;
a switch operatively connected to the receiving end portion and configured to perform switching to change a gain according to characteristics of the at least one antenna signal and generate the at least one conversion signal;
a frequency power detector operatively connected to the switch and configured to generate frequency information and power information using the at least one conversion signal; and a symptom detector operatively connected to the frequency power detector and configured to classify an electromagnetic wave using the frequency information and the power information.

The receiving end portion, the switch, the frequency power detector, and the symptom detector may be embedded in a single chip device.

The receiving end portion may include at least one amplifier configured in parallel.

The at least one amplifier may be a variable gain amplifier, and is configured to perform variable gain amplification under control of the symptom detector.

The frequency power detector may include:
a frequency generator configured to generate phase frequency signals including different phases;
a mixer operatively connected to the switch and the frequency generator and configured to generate a synthesized signal by mixing the conversion signal and the phase frequency signals;
a filter operatively connected to the mixer and configured to generate a real number signal and an imaginary number signal by filtering the synthesized signal;
an adder operatively connected to the filter and configured to generate the power information of electromagnetic waves by multiplying the real number signal and the imaginary number signal; and
an analog-digital converter (ADC) operatively connected to the adder and configured to convert the power information from analog information to digital information.

The frequency generator may perform a frequency sweep mode of changing at a specific frequency over time during operation of the electromagnetic wave detection device in order to detect the specific frequency.

The electromagnetic wave detection device may include an output processor operatively connected to the frequency power detector and configured to output-process the frequency information and the power information.

The switch may include a structure to select one input among a plurality of inputs and produce one output.

The switch may include at least one switching element connected in one-to-one correspondence to at least one amplifier provided in parallel at the receiving end portion.

In another aspect, the present disclosure provides a method of controlling an electromagnetic wave detection device, the method including:
receiving by a receiving end portion at least one antenna signal from an antenna block and generating at least one conversion signal;
performing, by a switch, switching to change a gain according to characteristics of the at least one antenna signal and generate the at least one conversion signal;
generating, by a frequency power detector, frequency information and power information using the at least one conversion signal; and
classifying, by a symptom detector, an electromagnetic wave using the frequency information and the power information.

The generation of the frequency information and the power information may include:
generating phase frequency signals including different phases by a frequency generator;
generating a synthesized signal by mixing the conversion signal and the phase frequency signals by a mixer;
generating a real number signal and an imaginary number signal by filtering the synthesized signal by a filter;
generating the power information of electromagnetic waves by multiplying the real number signal and the imaginary number signal by an adder; and
converting the power information from analog information to digital information by an analog-digital converter (ADC).

The method may include output-processing the frequency information and the power information in a first in, first out (FIFO) method by the output processor.

According to an exemplary embodiment of the present disclosure, provided is a structure by which a frequency detector including a fast response rate and a function of classifying electromagnetic waves and generating a warning signal by analyzing a detection signal may be embedded in a single chip device.

As a further effect of the present disclosure, the structure according to an exemplary embodiment of the present disclosure may be incorporated into key electronics for the Fourth Industrial Revolution, such as autonomous vehicles, drones, urban air mobility (UAM), and robots, with a small size, light weight, low power, and low cost.

As a further effect of the present disclosure, the structure according to an exemplary embodiment of the present disclosure may be used as an electromagnetic black box for intra coupling (or internal electromagnetic disturbances). As a result, it is possible to detect the cause and/or situation of the electromagnetic disturbance and take appropriate countermeasures accordingly.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating a configuration of an electromagnetic wave detection system according to an exemplary embodiment of the present disclosure.

FIG. 2 is a block diagram illustrating a specific configuration of the electromagnetic wave detection device illustrated in FIG. 1.

FIG. 3 is a block diagram illustrating a specific configuration of the switch illustrated in FIG. 2.

FIG. 4 is a block diagram illustrating a specific configuration of the frequency detector illustrated in FIG. 2.

FIG. 5 is a block diagram illustrating a specific configuration of the symptom detector illustrated in FIG. 2.

FIG. 6 is a flowchart illustrating an electromagnetic wave detection process of according to an exemplary embodiment of the present disclosure.

FIG. 7 is an operation waveform in a case where the frequency of an antenna signal (RF signal) is the same as the frequency of the frequency generator according to an exemplary embodiment of the present disclosure.

FIG. 8 is an operation waveform in a case where an antenna frequency is different from the frequency of the frequency generator according to an exemplary embodiment of the present disclosure.

FIG. 9 is a graph of a sweep frequency illustrating changes over time of the frequency generator according to an exemplary embodiment of the present disclosure.

FIG. 10 is a waveform when a specific frequency is detected in the frequency sweep mode in FIG. 9.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The foregoing objects, features, and advantages will be further described in detail with reference to the accompanying drawings, by which those including ordinary skill in the art to which the present disclosure pertains may readily practice the technical ideas of the present disclosure. In description of the present disclosure, detailed description will be omitted where it is considered that a detailed description of the known art to which the present disclosure relates would unnecessarily obscure the essence of the present disclosure. Hereinafter, example embodiments of the present disclosure will be described in detail with reference to the accompanying drawings. In the drawings, like reference numerals will be used to designate the same or similar components.

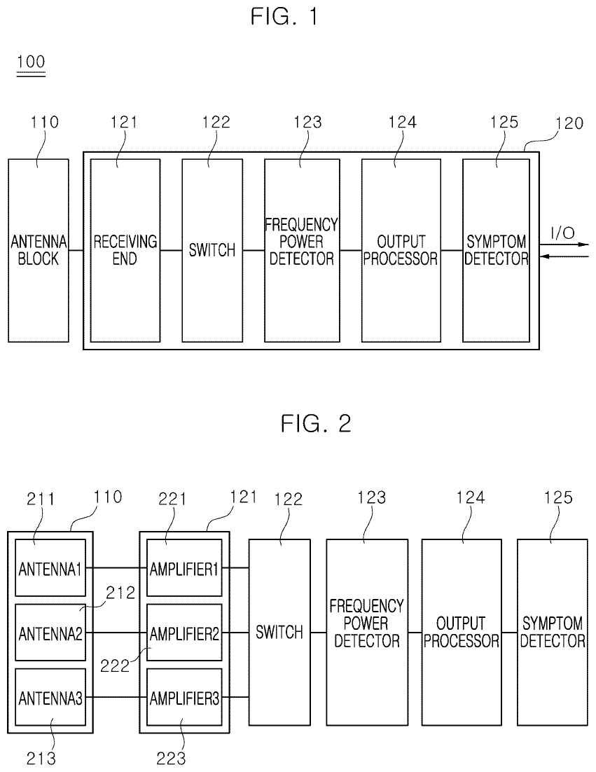

FIG. 1 is a block diagram illustrating a configuration of an electromagnetic wave detection system 100 according to an exemplary embodiment of the present disclosure. Referring to FIG. 1, the electromagnetic wave detection system 100 includes an antenna block 110 generating an antenna signal, an electromagnetic wave detection device 120 receiving the antenna signal and detecting a symptom by electromagnetic wave classification, and the like.

The antenna block 110 includes a plurality of antennae to perform generating antenna signals. Antenna signals may be radio frequency (RF) signals.

The electromagnetic wave detection device 120 is configured to perform receiving a plurality of antenna signals from the antenna block 110 and classifying electromagnetic waves to detect a symptom. In this regard, the electromagnetic wave detection device 120 may include: a receiving end portion 121 receiving an antenna signal and generating a plurality of conversion signals; a switch 122 performing switching to change a gain according to characteristics of the received antenna signal; a frequency power detector 123 generating frequency information and power information using the connected conversion signals in response to the switching of the switch 122; an output processor 124 output-processing the generated frequency information and power information; a symptom detector 125 classifying an electromagnetic wave using the frequency information and the power information.

The receiving end portion 121 is connected to the antenna block 110 and is configured to perform receiving the antenna signal and converting the antenna signal to generate the conversion signal.

The switch 122 is configured to perform changing the gain according to the magnitude of the antenna signal received at the receiving end portion 121 to generate the conversion signal and connecting the conversion signal to the frequency power detector 123.

The frequency power detector 123 is configured to perform generating frequency information and/or power information by processing the conversion signal connected by the switch 122.

The output processor 124 is configured to perform processing the output of frequency information and/or power information generated by the frequency power detector 123. The output processor 124 is configured to perform adjusting the output order of the frequency information and/or the power information successively generated.

The symptom detector 125 is configured to perform detecting power and frequency over time using frequency information and/or power information to discriminate an electromagnetic wave type and transmit the electromagnetic wave type to a higher level controller. The symptom detector 125 transmits and receives data to or from the higher level controller via input/output (I/O).

FIG. 2 is a block diagram illustrating a specific configuration of the electromagnetic wave detection device 120 illustrated in FIG. 1. Referring to FIG. 2, the antenna block 110 includes first, second, and third antennae 211, 212, and 213 provided in parallel. The first, second, and third antennae 211, 212, and 213 may be of the same type or different types in accordance with the wave. Each of the first, second, and third antennae 211, 212, and 213 may be, for example, a dipole, monopole, horn, or patch antenna.

Furthermore, the first, second, and third antennae 211, 212, and 213 may be positioned at physically different locations to detect time differences in the arrival of electromagnetic waves.

In contrast, the first, second, and third antennae 211, 212, and 213 may be antennae directed in respective directions in a form of X/Y/Z.

The receiving end portion 121 may include an input port for receiving antenna signals from the first, second, and third antennae 211, 212, and 213, first, second, and third amplifiers 221, 222 and 223, and the like. The antenna block 110 and the receiving end portion 121 are connected by a wired medium such as coaxial cable.

The receiving end portion 121 may include the first, second, and third amplifiers 221, 222 and 223 which may be provided in parallel, and may be variable gain amplifiers (VGAs). Such a VGA is configured to perform variable gain amplification under the control of the symptom detector 125.

The switch 122 is configured to connect any input to the frequency power detector 123. The switch 122 is configured to perform connecting one of the conversion signals generated by the first, second, and third amplifiers 221, 222 and 223 to the frequency power detector 123.

The frequency power detector 123 is configured to perform generating frequency information and/or power information from the conversion signal.

The output processor 124 is connected to the frequency power detector 123 and is configured to perform processing the output of frequency information and/or power information generated by the frequency power detector 123. The output processor 124 is configured to perform storing frequency information and/or power information successively generated and adjusting the order of outputs thereof. In general, a first in, first out (FIFO) method may be used, but the present disclosure is not limited thereto, and a last in, first out (LIFO) method may also be used.

The symptom detector 125 is configured to perform obtaining frequency information and/or power information from the output processor 124 in the FIFO method or the like, and when there is a set input signal magnitude in a set frequency, detecting the same.

The number of the antennae 211, 212, and 213, the number of the amplifiers 221, 222, and 223, and the number of the output processors 124 illustrated in FIG. 2 are for illustrative purposes only, and are not intended thereto. A greater number of antennae, amplifiers, or processors may be provided.

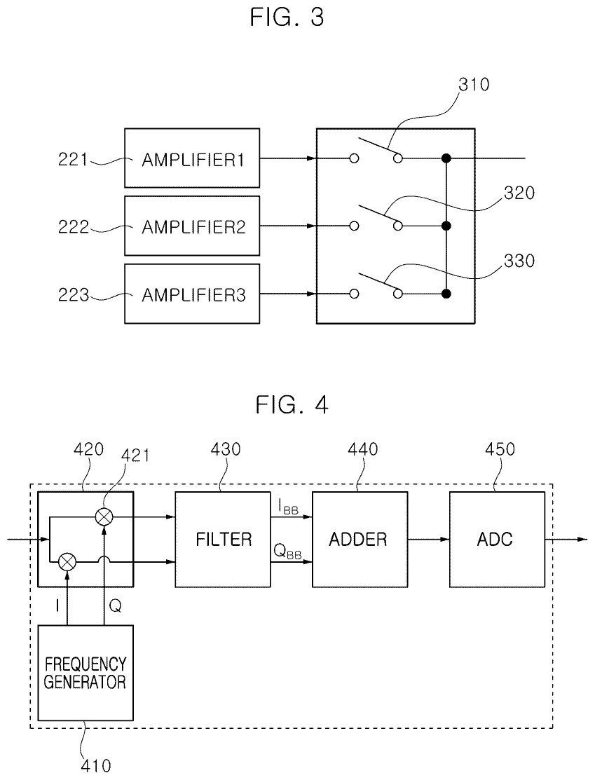

FIG. 3 is a block diagram illustrating a specific configuration of the switch 122 illustrated in FIG. 2. Referring to FIG. 3, the switch 122 is configured to perform connecting one of the outputs of the respective amplifiers 221, 222 and 223 to the frequency power detector 123 at the next end portion. In other words, first, second, and third switching elements 310, 320, and 330 are connected to the first, second, and third amplifiers 221, 222, and 223 in one-to-one correspondence. The outputs of the first, second, and third switching elements 310, 320, and 330 are connected as one. That is, the switch 122 is internally configured in a form of an analog multiplexer to select one input among a plurality of inputs and produce one output.

The first, second, and third switching elements 310, 320, and 330 may respectively be a field effect transistor (FET), a metal oxide semiconductor FET (MOSFET), or the like. An MOSFET includes a complementary metal oxide semiconductor (CMOS) structure.

FIG. 4 is a block diagram illustrating a specific configuration of the frequency power detector 123 illustrated in FIG. 2. Referring to FIG. 4, the frequency power detector 123 may include a frequency generator 410, a mixer 420, a filter 430, an adder 440, an analog-to-digital converter (ADC) 450, and the like.

The frequency generator 410 generates phase frequency signals having different phases (or out of phase). That is, the frequency generator 410 is configured to perform generating frequencies having a 90° phase. The frequency generator 410 generates an in-phase (I) frequency and a quadrature-phase (Q) frequency each of which includes a 90° phase.

The mixer 420 mixes conversion signals connected through the switch 122 with phase frequency signals. That is, the mixer 420 is configured to perform multiplying an I frequency by a multiplier 421 and multiplying a conversion signal with a Q frequency to generate a two-dimensional synthesized signal. The mixer 420 is a quadrature down conversion mixer serving to perform down conversion to an input signal.

The filter 430 filters synthesized signals to generate a real number signal I_{BB} and an imaginary number signal Q_{BB}. The filter 430 may be a low pass filter. Thus, the filter 430 selects only signals in a corresponding frequency band by filtering the synthesized signals to generate the real number signal I_{BB} and the imaginary number signal Q_{BB}. Here, BB refers to base band.

The adder 440 is configured to perform generating a sum-of-squares signal (i.e., the power information of the electromagnetic wave) by summing the squares of the real number signal I_{BB} and the imaginary number signal Q_{BB}. That is, the power P is P=I_{BB}²+Q_{BB}².

The ADC 450 is configured to perform converting analog power information to digital power information. That is, the ADC 450 converts the power information from analog to digital.

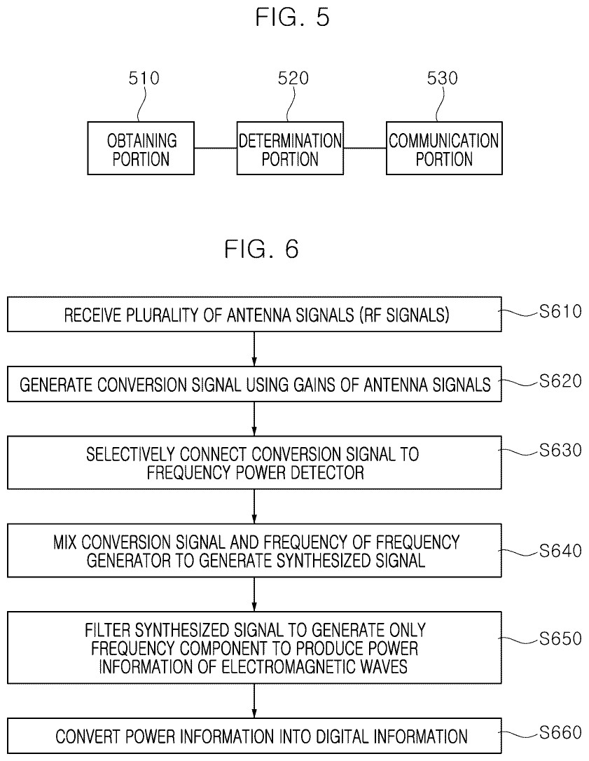

FIG. 5 is a block diagram illustrating a specific configuration of the symptom detector 125 illustrated in FIG. 2. Referring to FIG. 5, the symptom detector 125 may include an obtaining portion 510 obtaining power information, a determination portion 520 comparing the obtained power information and a predetermined input signal magnitude, and based on the result of the comparison, determining that an antenna signal to be symptomatic, a communication portion 530 extracting characteristics of the antenna signal determined to be symptomatic and transmitting the characteristics to a higher level controller, and the like.

The obtaining portion 510 is configured to perform obtaining, from the output processor 124, power information, frequency information, and the like stored therein.

The determination portion 520 compares the obtained power information with the predetermined input signal magnitude, and based on the result of the comparison, is configured to determine the antenna signal to be symptomatic. The determination portion 520 is configured to determine whether the current antenna signal corresponds to the magnitude of EMI or IEMI, and if so, is configured to determine the antenna signal to be symptomatic.

In the case of EMI or IEMI, a value significantly greater than a normal input is input, and the input value may be identified as EMI or IEMI. In another example, the signal may be distinguished from existing signals by integrating the magnitude of an EMI energy value or detecting the peak thereof.

It is also possible to extract characteristics of the antenna signal. The characteristics of the antenna signal may include the number of the antenna, the frequency waveform and amplitude of the antenna signal, and the like.

The determination portion 520 is configured to read and analyze data from the output processor 124 in which the frequency information and/or the power information generated by the frequency power detector 123 are stored, extract characteristics of the currently input frequency, and transmit the extracted characteristics to a higher level controller via I/O.

The higher level controller is configured to determine the operation mode of the electromagnetic wave detection device 120 via I/O, and when a signal including a particular pattern is detected, performs necessary processing. The higher level controller may be an electronic control unit (ECU), a hybrid control unit (HCU), or the like.

The communication portion 530 is configured to perform transmitting data by establishing communication with the higher level controller. In this regard, the communication portion 530 may include a communication circuit, a microprocessor, and the like.

The obtaining portion 510 and the determination portion 520 illustrated in FIG. 5 respectively refer to a unit that processes at least one function or operation, which may be implemented as software and/or hardware. In hardware implementation, such a component may be implemented as any device designed to perform the function described above, such as an application specific integrated circuit (ASIC), a digital signal processor (DSP), a programmable logic device (PLD), a field programmable gate array (FPGA), a processor, a microprocessor, another electronic unit, or a combination thereof.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well known to a person having ordinary knowledge in the art.

Furthermore, the symptom detector 125 may further read and analyze the data stored in the output processor 124 so that appropriate processing may be performed.

FIG. 6 is a flowchart illustrating an electromagnetic wave detection process of according to an exemplary embodiment of the present disclosure. Referring to FIG. 6, the electromagnetic wave detection device 120 receives a plurality of antenna signals from the antenna block 110 (step S610).

Thereafter, the receiving end portion 121 generates a conversion signal by adjusting the gain of the received antenna signal (step S620).

Subsequently, the switch 122 selectively connects the conversion signal to the frequency power detector 123 (step S630).

Thereafter, the frequency power detector 123 generates a synthesized signal by mixing the conversion signal and the frequency of the frequency generator 410 (step S640).

Subsequently, the frequency power detector 123 generates only set frequency components by filtering the synthesized signal, producing power information of the electromagnetic wave and converts the power information into digital information to be stored in the output processor 124 (steps S650 and S660). Here, the symptom detector 125 obtains digital information from the output processor 124, compares the antenna signal with a set input signal magnitude within a set frequency, and transmits the result of the comparison to the higher level controller.

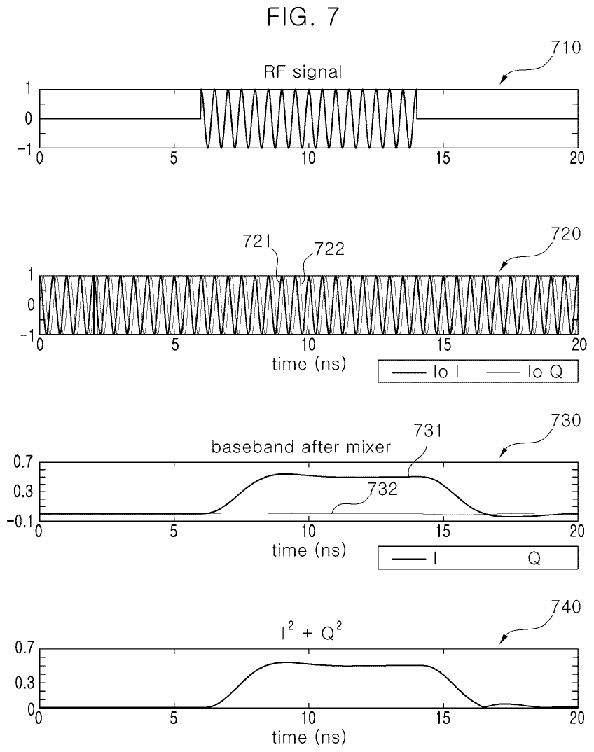

FIG. 7 is an operation waveform in a case where the frequency of an antenna signal (RF signal) is the same as the frequency of the frequency generator 410 according to an exemplary embodiment of the present disclosure.

Referring to FIG. 7, a waveform 710 representing an antenna frequency, a waveform 720 representing a frequency generated by the mixer 420, a waveform 730 representing a baseband signal converted to baseband and filtered after being generated by the mixer 420, and a waveform 740 representing a sum-of-squares signal I²+Q² of the filtered baseband signal are illustrated in the order from top to bottom.

The waveform 720 illustrates an I signal 721 and a Q signal 722 generated by the frequency generator 410. That is, the frequency generator 410 generates the I signal 721 and the Q signal 722, which are out of phase, using a local oscillator. Here, the phase is 90°.

In the waveform 730, the I signal 731 is in a form of a pattern including an interval increasing over time from a predetermined time to a predetermined value, followed by a flat interval and a decreasing interval. On the other hand, the Q signal 732 is more or less constant over time.

In waveform 740, the power signal includes a similar shape to the I signal 731 in the waveform 730. In the instant case, the magnitude of the Q-signal is zero (0).

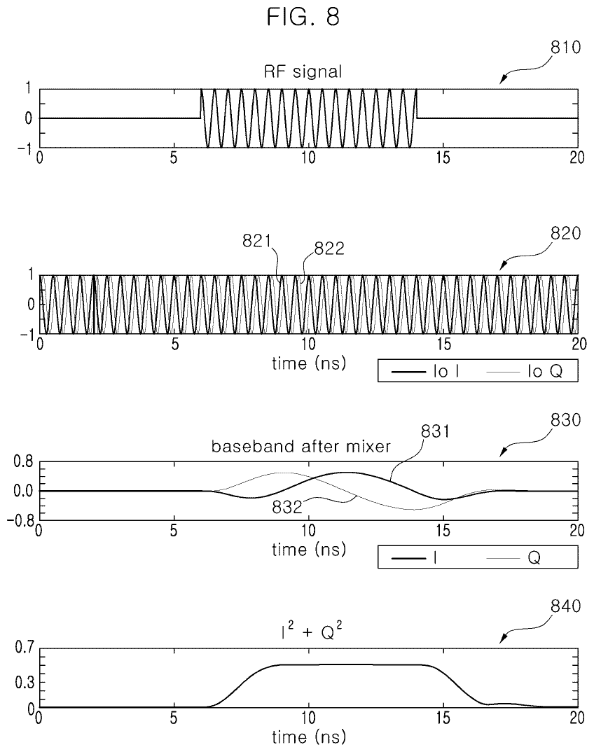

FIG. 8 is an operation waveform in a case where an antenna frequency is different from the frequency of the frequency generator 410 according to an exemplary embodiment of the present disclosure. Referring to FIG. 8, a waveform 810 representing an antenna frequency, a waveform 820 representing a frequency generated by the mixer 420, a waveform 830 representing a baseband signal converted to baseband and filtered after being generated by the mixer 420, and a waveform 840 representing the sum of squares of the filtered baseband signal I²+Q² are illustrated in the order from top to bottom.

The waveform 820 shows an I signal 821 and a Q signal 822 generated by the frequency generator 410. That is, the frequency generator 410 generates the I signal 821 and the Q signal 822, which are out of phase, using a local oscillator. Here, the phase is 90°.

In the waveform 830, the I signal 831 and the Q signal 832 are irregularly shaped without forming a regular pattern. This is a case where the frequencies of the RF signal and the frequency generator 410 are not the same but are similar. In the instant case, a baseband signal having a frequency equal to the present frequency difference is generated.

In the waveform 840, the power signal includes a similar shape to the I signal 731 in the waveform 730. That is, the shape of the I and Q signals squared does not change in magnitude over time.

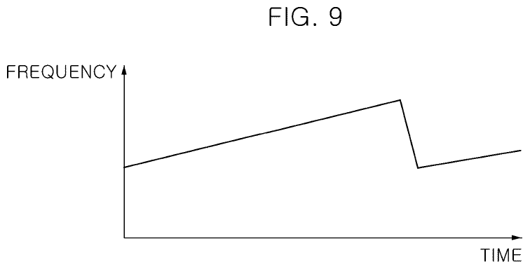

FIG. 9 is a graph of a sweep frequency illustrating changes over time of the frequency generator according to an exemplary embodiment of the present disclosure. Referring to FIG. 9, this is a case where the frequency of the frequency generator 410 sweeps during the operation of the electromagnetic wave detection device 120. A frequency sweep mode of changing at a specific frequency over time is performed. In the present manner, the frequency of a currently input signal may be accurately determined.

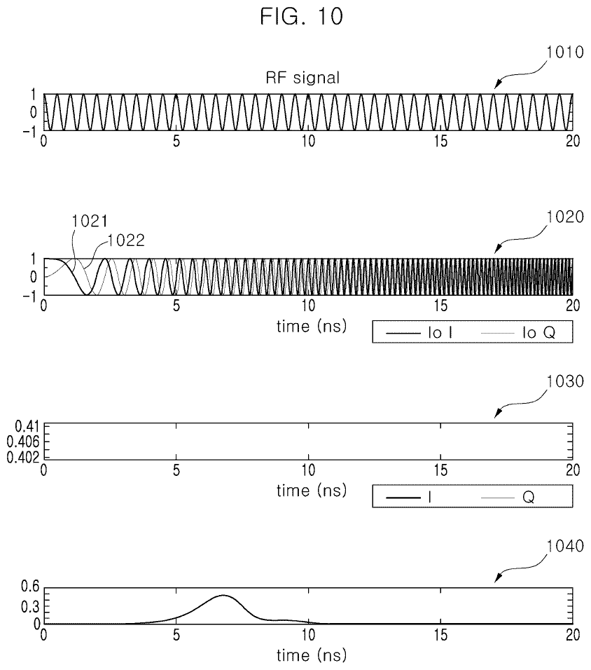

FIG. 10 is a waveform when a specific frequency is detected in the frequency sweep mode in FIG. 9. Referring to FIG. 10, a waveform 1010 representing an antenna frequency, a waveform 1020 representing a frequency generated by the mixer 420, a waveform 1030 representing a filtered baseband signal converted to baseband after being generated by the mixer 420, and a waveform 1040 representing a sum-of-squares signal I²+Q² of the filtered baseband signal are illustrated in the order from top to bottom.

In the waveform 1020, the I signal 1021 and the Q signal 1022 generated by the frequency generator 410 are illustrated. That is, the frequency generator 410 generates the I signal 1021 and the Q signal 1022, which are out of phase, using a local oscillator. The signals change at a specific frequency over time.

The waveform 1030 is shaped so that each of the I signal and the Q signal does not appear independent of time. In the portion of the waveform 1030 in which the I and Q signals are plotted, the time axis is a short interval around 11.875 ns. In the present portion, the signal is near zero and therefore has little value adjacent to a y value between 0.406 and 0.406.

In the waveform 1040, the I signal protrudes only in a specific time interval and is zero in other intervals.

Furthermore, the steps of the methods or the algorithms described with respect to the exemplary embodiments included herein may be implemented directly in hardware, implemented as software modules executed by hardware, or a combination thereof.

Software modules may be embedded in random access memory (RAM), read only memory (ROM), erasable programmable ROM (EPROM), electrically erasable programmable ROM (EEPROM), or flash memory.

Furthermore, the term related to a control device such as “controller”, “control apparatus”, “control unit”, “control device”, “control module”, “control circuit”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An electromagnetic wave detection apparatus comprising:
a receiving end portion configured to receive at least one antenna signal from an antenna block and to generate at least one conversion signal;
a switch operatively connected to the receiving end portion and configured to perform switching to change a gain according to characteristics of the at least one antenna signal and to generate the at least one conversion signal;
a frequency power detector operatively connected to the switch and configured to generate frequency information and power information using the at least one conversion signal; and
a symptom detector operatively connected to the frequency power detector and configured to classify an electromagnetic wave using the frequency information and the power information.

2. The electromagnetic wave detection apparatus of claim 1, wherein the receiving end portion, the switch, the frequency power detector, and the symptom detector are embedded in a single chip device.

3. The electromagnetic wave detection apparatus of claim 1, wherein the receiving end portion includes at least one amplifier configured in parallel.

4. The electromagnetic wave detection apparatus of claim 3, wherein the at least one amplifier is a variable gain amplifier, and is configured to perform variable gain amplification under control of the symptom detector.

5. The electromagnetic wave detection apparatus of claim 1, wherein the frequency power detector includes:
a frequency generator configured to generate phase frequency signals including different phases;
a mixer operatively connected to the switch and the frequency generator and configured to generate a synthesized signal by mixing the at least one conversion signal and the phase frequency signals;
a filter operatively connected to the mixer and configured to generate a real number signal and an imaginary number signal by filtering the synthesized signal;
an adder operatively connected to the filter and configured to generate the power information of electromagnetic waves by multiplying the real number signal and the imaginary number signal; and
an analog-digital converter (ADC) operatively connected to the adder and configured to convert the power information from analog information to digital information.

6. The electromagnetic wave detection apparatus of claim 5, wherein the frequency generator is further configured to perform generating frequencies having a 90° phase.

7. The electromagnetic wave detection apparatus of claim 5, wherein the frequency generator is further configured to perform a frequency sweep mode of changing at a predetermined frequency over time during operation of the electromagnetic wave detection apparatus to detect the predetermined frequency.

8. The electromagnetic wave detection apparatus of claim 1, further including an output processor operatively connected to the frequency power detector and configured to output-process the frequency information and the power information.

9. The electromagnetic wave detection apparatus of claim 1, wherein the switch includes a structure to select one input among a plurality of inputs and produce one output.

10. The electromagnetic wave detection apparatus of claim 9, wherein the switch includes at least one switching element connected in one-to-one correspondence to at least one amplifier provided in parallel at the receiving end portion.

11. A method of controlling an electromagnetic wave detection apparatus, the method including:
receiving, by a receiving end portion, at least one antenna signal from an antenna block and generating at least one conversion signal;
performing, by a switch operatively connected to the receiving end portion, switching to change a gain according to characteristics of the at least one antenna signal and generate the at least one conversion signal;
generating, by a frequency power detector operatively connected to the switch, frequency information and power information using the at least one conversion signal; and
classifying, by a symptom detector operatively connected to the frequency power detector, an electromagnetic wave using the frequency information and the power information.

12. The method as claimed in claim 11, wherein the receiving end portion, the switch, the frequency power detector, and the symptom detector are embedded in a single chip device.

13. The method as claimed in claim 11, wherein the receiving end portion includes at least one amplifier configured in parallel.

14. The method as claimed in claim 13, wherein the at least one amplifier is a variable gain amplifier, and is configured to perform variable gain amplification under control of the symptom detector.

15. The method as claimed in claim 11,
wherein the frequency power detector includes a frequency generator, a mixer, a filter, an adder and an analog-digital converter (ADC), and
wherein the generation of the frequency information and the power information includes:
generating phase frequency signals including different phases by the frequency generator;
generating a synthesized signal by mixing the at least one conversion signal and the phase frequency signals by a mixer operatively connected to the switch and the frequency generator;
generating a real number signal and an imaginary number signal by filtering the synthesized signal by a filter operatively connected to the mixer;
generating the power information of electromagnetic waves by multiplying the real number signal and the imaginary number signal by an adder operatively connected to the filter; and
converting the power information from analog information to digital information by the analog-digital converter (ADC) of the frequency power detector operatively connected to the adder.

16. The method of claim 15, wherein the frequency generator is further configured to perform generating frequencies having a 90° phase.

17. The method as claimed in claim 15, wherein the frequency generator is configured to perform a frequency sweep mode of changing at a predetermined frequency over time during operation of the electromagnetic wave detection apparatus to detect the predetermined frequency.

18. The method as claimed in claim 11, including output-processing the frequency information and the power information in a first in, first out (FIFO) method by an output processor operatively connected to the frequency power detector.
